(19) United States
(12) Patent Application Publication
(10) Pub. No.: US 2019/0269012 A1
(43) Pub. Date: Aug. 29, 2019

(54) THERMOPLASTIC COMPOSITION

(71) Applicant: DSM IP Assets B.V., Heerlen (NL)

(72) Inventor: Frank Peter Theodorus Johannes VAN DER BURGT, Echt (NL)

(21) Appl. No.: 16/346,231

(22) PCT Filed: Nov. 11, 2017
(86) PCT No.: PCT/EP2017/080908

§ 371 Date: Apr. 30, 2019

(30) Foreign Application Priority Data
Nov. 30, 2016 (EP) 16201297.5

(51) Int. Cl. H05K 1/03; C08L 77/00; C08L 67/02; C08K 3/22; C08K 7/14; C08K 5/5313

(52) U.S. Cl. CPC H05K 1/0373; C08L 77/00; C08L 67/02; H05K 3/185; C08K 7/14; C08K 5/5313; C08K 3/22

(57) ABSTRACT

The invention relates to a thermoplastic composition comprising a thermoplastic polymer, a laser direct structuring (LDS) additive and a LDS synergist, wherein the composition comprises: (A) a thermoplastic polymer; (B) a LDS additive comprising a tin-based metal oxide; and (C) a metal salt of a phosphinic acid or a diphosphinic acid, or any mixtures thereof.

The present invention relates to a thermoplastic composition comprising a thermoplastic polymer and a laser direct structuring (LDS) additive, as well as a synergistic component, and more particular to light colored and white LDS compositions. The invention also relates to a process for producing a circuit carrier by a laser direct structuring process. The invention also relates to a circuit carrier obtainable thereby.

Polymer compositions comprising a polymer and a laser direct structuring (LDS) additive are for example described in US-2012/0279764-A1, US-2014/002311-A1 and US-2015/035720-A1. Such polymer compositions can be used advantageously in an LDS process for producing a non-conductive part on which conductive tracks are to be formed by irradiating areas of said part with laser radiation to activate the plastic surface at locations where the conductive path is to be situated and subsequently metalizing the irradiated areas to accumulate metal on these areas.

US-2012/0279764-A1 discloses a thermoplastic composition that is capable of being used in a laser direct structuring process to provide enhanced plating performance and good mechanical properties. The compositions of that invention include a thermoplastic base resin, a laser direct structuring additive and a white pigment. The pigments comprise TiO2 and materials chosen from the group of anatase TiO2, rutile TiO2, ZnO, BaSO4 and BaTiO3. The laser direct structuring additive is a heavy metal mixture oxide spinel, such as copper chromium oxide spine; a copper salt, such as copper hydroxide, copper phosphate, copper sulfate, cuprous thiocyanate; or a combination. The pigments exhibited a synergistic effect with the laser activatable additive thereby improving the plating performance of the LDS composition.

US-2014/002311-A1 describes a molded article made from a thermoplastic composition comprising a thermoplastic resin, a LDS additive comprising at least one of copper, antimony or tin, and inorganic fiber. The LDS additive has a Mohs hardness of 1.5 or more below the Mohs hardness of the inorganic fiber.

US-2015035720-A1 describes a thermoplastic composition comprising a thermoplastic resin and a LDS additive comprising a metal oxide comprising a mixed metal oxide of at least tin and a second metal from one or more of antimony, bismuth, aluminum and molybdenum.

Although the LDS additives known in the prior art are satisfactory in certain situations, good results are more easily received with compositions comprising spinel based metal oxides as LDS additive, which additives are typically dark colored or black, than with light colored LDS additives such as nickel based oxides. Improved LDS performance is achieved, for example, by using special mixed metal compounds for the spinel compounds, or for the tin based oxides, or by using additional additives, such as TiO2, which synergistic effect has been shown in combination with spinel based compounds. However, TiO2 also has a negative effect on the mechanical properties of glass fiber reinforced LDS compositions.

Apart from the above, there is a constant need for materials with improved LDS performance, while retaining reasonable mechanical properties, in particular for light-colored-to-white compositions.

An object of the present invention therefore is to provide a thermoplastic composition capable of being used in a laser direct structuring process with improved LDS properties. Another object of the invention is to provide a light-colored-to-white thermoplastic composition capable of being used in a laser direct structuring process with improved LDS properties. A further object of the present invention is to provide a thermoplastic composition capable of being used in a laser direct structuring process with improved LDS properties, with retention of good mechanical properties, in particular retention of elongation at break and impact.

According to the invention, the main object is reached by the composition comprising (A) a thermoplastic polymer, (B) a laser direct structuring (LDS) additive and (C) a LDS synergist with the features of claim 1.

The thermoplastic composition of the present invention comprises:
(A) a thermoplastic polymer;
(B) a LDS additive comprising a tin-based metal oxide; and
(C) a metal salt of a phosphinic acid or a diphosphinic acid, or any mixtures thereof, in an amount of 0.5-7 wt. %, relative to the weight of the total composition.

With the term tin-based metal-oxide is herein understood a metal oxide comprising or consisting of SnO or SnO2, or a combination thereof. When the LDS additive comprising the tin-based metal oxide is to be understood as a metal oxide consisting of SnO or SnO2 or a mixture thereof, the LDS additive comprising the tin-based metal oxide can be designated as tin oxide. The metal oxide may also comprise a mixture of metal oxides, thus comprising further metal oxides next to tin oxide.

In a specific embodiment of the invention, the composition further comprises at least a reinforcing agent (component D).

In another specific embodiment, the composition has a CIELab colour value L* of at least 70.

In an even more specific embodiment, the composition comprises a reinforcing agent (component D) and has a CIELab colour value L* of at least 70.

It was found according to the present invention that a LDS additive comprising a tin-based metal oxide can be used for plating, as well for making light colored compositions, but does not give enough plating without a certain amount of the LDS synergist (C). Surprisingly, the effect of the compositions according to the invention, comprising component (C) which is a metal salt of a phosphinic acid or a metal salt of a diphosphinic acid, or any mixtures thereof, as an LDS synergist is first of all that the plating is improved, compared to compositions not comprising the metal salt (C) as defined in the present invention. Under identical plating conditions a thicker plating metal layer is obtained or a certain layer thickness is achieved in a shorter time and/or under less energy demanding conditions. Furthermore, compositions can be prepared combining a light color and good plating behavior. In addition, in reinforced LDS compositions, the LDS properties are improved while mechanical properties are well retained, compared to corresponding compositions not comprising the metal salt (C). Ultimately, light-colored-to-white reinforced LDS compositions can be prepared, with less to none TiO2, while achieving good LDS properties, and retaining good mechanical properties compared to thermoplastic composition not comprising components (A), (B) and (C) as defined in the present invention.

The composition according to the invention may have different colors, with a lightness varying over a wide range. The composition may in principle even have a relative dark color, though light colors are preferred. The composition according to the invention, and the various embodiments thereof, suitably have a CIE-Lab color value L* (also known as whiteness or lightness parameter) of at least 50, better at least 60. Preferably the L* value is at least 70, more preferably at least 80, and still more preferably at least 90. The advantage of the composition having such high lightness parameter is that the composition is suitable for a wider range of applications and designs requiring light colors and involving LDS technology, while still having the advantageous LDS performance of the present invention.

Herein the L* value is a measure for the lightness of a color according to the “CIELab” index (CIE 1976). [CIE is the Commission Internationale de l'Eclairage (translated as the International Commission on Illumination), i.e. the body responsible for international recommendations for photometry and colorimetry]. This index refers to color measurements made under D65 illumination, which is a standard representation of outdoor daylight. For a color expressed in CIELAB parameters, L* defines lightness, a* denotes the red/green value and b* the yellow/blue value. In this L*a*b* colorimetric system, L* refers to lightness expressed by a numerical value of from 0 to 100, in which L*=0 means that the color is complete black, and L*=100 means that the color is complete white. The CIELab L* value as utilized herein, is to define the darkness/lightness of the polymer composition, as well as of the LDS additive, where applicable.

The thermoplastic polymer (component (A)) in the thermoplastic composition according to the invention can be any thermoplastic polymer suitable for use in a circuit carrier. The thermoplastic polymer may be a polyamide, a polyester, such as PET or PBT, a polycarbonate, a liquid crystalline polymer, polystyrene, a poly(meth)acrylate, such as PMMA, a polyester elastomer, a polyamide elastomer, a polyesteramide block copolymer, a rubber, or any mixtures thereof. In a particular embodiment, the thermoplastic polymer comprises a polymer selected from the group consisting of a polyamide, a polyester, a polycarbonate and any mixtures thereof. These polymers are eminently suitable for making structural parts combined with the function of the circuit carrier.

Suitably, the polyamide is an aliphatic polyamide, or a semi-aromatic polyamide, or a mixture thereof. The polyamide suitably comprises a semi-crystalline polyamide, more particularly a semi-crystalline semi-aromatic polyamide, optionally in a mixture with an amorphous polyamide, or consists of a semi-crystalline polyamide

In a preferred embodiment, the thermoplastic polymer comprises a thermoplastic polymer with a melting temperature of at least 270° C., more preferably at least 280° C., and still more preferably in the range of 280-350° C., or even better 300-340° C. Thus, the composition will be better capable to withstand severe conditions, applied in a surface mount technology (SMT) process involving lead free soldering. The person skilled in the art of making polyamide molding compositions will be capable of making and selecting such polymers.

In case of a polyamide a higher melting temperature can generally be achieved by using semi-aromatic polyamides with a higher content in terephthalic acid and/or shorter chain diamines in the polyamide.

Suitably, the semi-crystalline semi-aromatic polyamide has a melting enthalpy of at least 15 J/g, preferably at least 25 J/g, and more preferably at least 35 J/g. Herein the melting enthalpy is expressed relative to the weight of the semi-crystalline semi-aromatic polyamide.

With the term melting temperature is herein understood the temperature, measured by the DSC method according to ISO-11357-1/3, 2011, on pre-dried samples in an N2 atmosphere with heating and cooling rate of 10° C./min. Herein Tm has been calculated from the peak value of the highest melting peak in the second heating cycle. With the term melting enthalpy is herein understood the measured by the DSC method according to ISO-11357-1/3, 2011, on pre-dried samples in an N2 atmosphere with heating and cooling rate of 10° C./min. Herein the melting enthalpy is measured from the integrated surface below the melting peak(s).

Suitably, the amount of the thermoplastic polymer is in the range of 30-80 wt. %, preferably 40-70 wt. %, relative to the total weight of the composition.

In the composition according to the invention, the key components (B) and (C) can also be present in amounts varying over a wide range.

Suitably, the composition comprises at least 1 weight percent (wt. %) of the LDS additive (B), i.e. the LDS additive comprising the tin-based metal oxide, relative to the total weight of the composition. Preferably, the LDS additive comprising the tin-based metal oxide is present in an amount in the range of 1-15 wt. %. More preferably, the amount is in the range of 2-10 wt. %. Herein the weight percentages (wt. %) are relative to the total weight of the composition. A higher minimal amount increases the LDS effectiveness. A lower maximum amount allows for better mechanical properties, such as improved elongation at break.

The composition comprises and at least 0.5 wt. % of the metal phosphinate synergist (C), relative to the total weight of the composition. Preferably, the synergist (C) is present in an amount in the range of 1-7 wt. %, More preferably, the amount is in the range of 1.5-6 wt. %, even more preferably 2-5 wt. %. Herein the weight percentage (wt. %) are relative to the total weight of the composition. An amount less than 0.5 wt. % will have little effect on the LDS properties.

For the LDS process, the goal is the production of a conductive path on a molded part through formation of a laser etched surface, and formation of a plated metal layer during a subsequent plating process. The LDS additive is selected to enable the composition to be used in a laser direct structuring process. In such a LDS process, an article made of the thermoplastic composition comprising the LDS additive is exposed to a laser beam to activate metal atoms from the LDS additive at the surface of the thermoplastic composition. The LDS additive is selected such that, upon exposure to a laser beam, metal atoms are activated and exposed. In areas not exposed to the laser beam, no metal atoms are exposed. In addition, the LDS additive is selected such that, after being exposed to a laser beam, the etching area is capable of being plated to form conductive structure. As used herein “capable of being plated” refers to a material wherein a substantially uniform metal plating layer can be plated onto a laser-etched area and show a wide process window for laser parameters. The activated metal atoms act as nuclei for the plating process and enable adhesion of the metallization layer in the metallization or plating process. The conductive path can be formed by electroless plating process e.g. by applying a standard process, such as a copper plating process. Other electroless plating processes that may be used include, but are not limited to, gold plating, nickel plating, silver plating, zinc plating, tin plating or the like. Plating rate and adhesion of the plated layer are key evaluation requirements. The plating rate can be derived from the thickness of the plating layer upon specific plating time. The layer thickness can be determined by calibrated XRF measurement method by XRF using reference films with known thickness.

The LDS additive in the thermoplastic composition according to the invention, comprises a tin-based metal oxide. Herein the tin-based metal oxide may consist of tin oxide (i.e. SnO or SnO2, or a mixture thereof). Suitably, the LDS additive comprising the tin-based metal oxide comprises at least 20 wt. % of tin, relative to the total weight of the LDS additive comprising the tin-based metal oxide. The tin-based metal oxide may also comprise a mixed metal oxide, comprising tin and one or more further metals. Suitably, the metal oxide comprises an oxide of a second metal, next to the tin oxide. The second metal is preferably selected from the group consisting of antimony, bismuth, aluminum, molybdenum, and mixtures thereof. Preferably, the LDS additive comprising the tin-based metal oxide comprises, or consists of, an antimony-doped tin oxide.

The amount of the second metal may vary over a wide range. In a preferred embodiment, the LDS additive comprising the tin-based metal oxide comprises a mixed metal oxide comprising at least tin and a second metal selected from the group consisting of antimony, bismuth, aluminum and molybdenum, wherein the weight ratio of the second metal to tin is at least 0.01:1, more preferably 0.02:1. The advantage thereof is that the platability is further enhanced. The weight ratio of the second metal to tin is suitably at most 0.10:1, preferably at most 0.005:1. It is noted that the weight ratio is based on the metal, not on the oxides thereof.

The amounts of each of the metals present in the laser direct structuring additive may be determined by X-ray fluorescence analysis. XRF analysis may e.g. be done using AXIOS WDXRF spectrometer from PANalytical, in conjunction with the software Omnian.

In the composition according to the invention, the LDS additive comprising the tin-based metal oxide may consist of the metal oxide as such, for example in the form of particles of the metal oxide. The LDS additive comprising the tin-based metal oxide may also be mixed with other components, or may be combined, for example, with a carrier material. The carrier may be, for example, mica or TiO2, coated with the metal oxide comprising the tin-based metal oxide. Examples thereof are Lazerflair 825 (Mica coated with doped tin oxide) or Iriotec (TiO2 coated with a doped tin oxide), both from Merck KGaA. Herein the LDS additive comprising the tin-based metal oxide preferably comprises at least 20 wt. % of tin, relative to the total weight of the LDS additive comprising the tin-based metal oxide. It is noted that the weight percentage of tin is based on the amount of the tin, not on the oxide thereof.

Next to the thermoplastic polymer (component (A)) and the laser direct structuring (LDS) additive (component (B)), the composition of the present invention comprises an LDS synergist (component (C)). The LDS synergist present in the thermoplastic composition according to the present invention is a metal salt of a phosphinic acid or a metal salt of a diphosphinic acid, or any mixtures thereof. In the context of the present invention, the metal salts in component (C) are selected from the group consisting of aluminum salts, zinc salts of zinc and (any) mixtures thereof. The metal salts of a phosphinic acid or of a diphosphinic acid, or any mixtures thereof, are herein also referred to as metal salts of (di)phosphinic acids, or even shorter as metal (di)phosphinates and are to be understood and illustrated as follows: suitable metal salts of (di)phosphinic acids that can be used in the composition according to the present invention are, for example, a phosphinate of the formula (I), a diphosphinate of the formula (II):

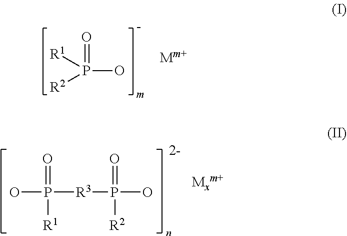

wherein R¹ and R² may be identical or different and are linear or branched C₁-C₆ alkyl and/or aryl; R³ is linear or branched C₁-C₁₀-alkylene, C₆-C₁₀-arylene, -alkylarylene or -arylalkylene; M is one or more of calcium ions, magnesium ions, aluminum ions and zinc ions, m is 2 or 3; n is 1 or 3; x is 1 or 2. Herein m in M^{m+} is the valency of the metal. R¹ and R² may be identical or different and are preferably methyl, ethyl, n-propyl, isopropyl, n-butyl, tert-butyl, n-pentyl and/or phenyl. R³ is preferably methylene, ethylene, n-propylene, isopropylene, n-butylene, tert-butylene, n-pantyliner, n-octylene, n-dodecylene, or phenylene or naphthylene, or methylphenylene, ethylphenylene, tert-butylphenylene, methylnaphthylene, ethylnaphthylene or tert-butylnaphthylene, or phenylmethylene, phenylethylene, phenylpropylene or phenylbutylene. M is preferably chosen to be an aluminum ion or zinc ion. These compounds are disclosed in U.S. Pat. No. 6,255,371 which is incorporated herein by reference.

Preferred metal (di)phosphinates are aluminum methylethylphosphinate and/or aluminum diethylphosphinate, more preferably aluminum diethylphosphinate. The advantage of the metal (di)phosphinates comprising or consisting of an aluminum salt of (di)phosphinic acid is that the plating rate of the LDS process is even further enhanced resulting in thicker metal layers in the same time or in achievement of a certain layer thickness in even shorter time or less energy demanding conditions. A further advantage is that the synergistic effect on the LDS properties is already achieved at a very low amount of the metal (di)phosphinate.

It is noted that such a metal (di)phosphinate comprising aluminum can suitably be combined with a LDS additive comprising the tin-based metal oxide, wherein the LDS additive comprising the tin-based metal oxide comprises a mixed metal oxide as mentioned further above, comprising tin and aluminum as the second metal.

The thermoplastic composition according to the invention optionally comprises a reinforcing agent (component D). More particularly, the composition does not necessarily need to comprise a reinforcing agent, though in a special embodiment, a reinforcing agent is present. The reinforcing agent, if used at all, is suitably present in an amount in the range of 5-60 wt. %, relative to the total weight of the composition. Suitably, the amount of (D) is in a more restricted range of 10-50 wt. %, more particular 20-40 wt. %, relative to the total weight of the composition.

Herein the reinforcing agent suitably comprises fibers or fillers or a mixture thereof, more particular fibers and fillers of inorganic material. Examples thereof include the following fibrous reinforcing agents: glass fibers, carbon fibers, and mixtures thereof. Examples of suitable inorganic fillers that the composition may comprise, include one or more of glass beads, glass flakes, kaolin, clay, talc, mica, wollastonite, calcium carbonate, silica and potassium titanate.

Fibers, or fibrous reinforcing agents, are herein understood to be materials having an aspect ratio L/D of at least 10. Suitably, the fibrous reinforcing agent has an L/D of at least 20. Fillers are herein understood to be materials having an aspect ratio L/D of less than 10. Suitably, the filler has an L/D of less than 5. In the aspect ratio LID, L is the length of an individual fiber or particle and D is the diameter or width of an individual fiber or particle.

In a special embodiment of the present invention, the component (D) in the composition comprises 5-60 wt. % of a fibrous reinforcing agent (D.1) having an L/D of at least 20, and 0-55 wt. % of an inorganic filler (D.2) having an L/D of less than 5, wherein the combined amount of (D.1) and (D.2) is 60 wt. % or less, the weight percentages herein being relative to the total weight of the composition.

Preferably, component (D) comprises a fibrous reinforcing agent (D.1) and optionally an inorganic filler (D.2), wherein the weight ratio (D.1):(D.2) is in the range of 50:50-100:0.

Also preferably, the reinforcing agent comprises, or even consists of glass fibers. In a particular embodiment, the composition comprises 5-60 wt. %, of glass fibers, more particular 10-50 wt. %, even more particular 20-40 wt. %, relative to the total weight of the composition.

In a particular embodiment of the invention, the composition comprises:
(A) 30-80 wt. % of the thermoplastic polymer;
(B) 1-15 wt. % of the LDS additive comprising the tin-based metal oxide;
(C) 1-7 wt. % of the metal salt of phosphinic acid or diphosphinic acid, or any mixtures thereof;
(D) 0-60 wt. % of a reinforcing agent;
wherein the sum of (A), (B), (C) and (D) is at most 100 wt. %, and wherein the weight percentages (wt. %) are relative to the weight of the total composition.

In a more particular embodiment thereof, the composition comprises:
(A) 30-80 wt. % of the thermoplastic polymer;
(B) 1-15 wt. % of LDS additive comprising the tin-based metal oxide comprising antimony-doped tin oxide; and
(C) 1-5 wt. % of the metal salt of phosphinic acid or diphosphinic acid, or any mixtures thereof;
(D) 0-60 wt. % of a reinforcing agent;
   wherein the sum of (A), (B), (C) and (D) is at most 100 wt. %, and wherein the weight percentages (wt. %) are relative to the weight of the total composition.

In a more particular embodiment thereof, the composition comprises:
(A) 30-80 wt. % of the thermoplastic polymer;
(B) 1-15 wt. % of the LDS additive comprising the tin-based metal oxide comprising antimony-doped tin oxide; and
(C) 1-5 wt. % of the metal salt of phosphinic acid or diphosphinic acid, or any mixtures thereof;
(D) 5-60 wt. % of a reinforcing agent;
wherein the sum of (A), (B), (C) and (D) is at most 100 wt. %, and wherein the weight percentages (wt. %) are relative to the weight of the total composition.

The thermoplastic composition according to the invention may optionally comprise one or more further components (E), next to components (A), (B), (C) and (D), in such case, the sum of (A), (B), (C), (D) and (E) is at most 100 wt. %, and the weight percentages (wt. %) are relative to the weight of the total composition. Further components (E) that may be added to the composition include impact modifiers, flame retardants and flame-retardant synergists, as well as any other auxiliary additive, or combination of additives, generally used in thermoplastic compositions or known by one skilled in the art and suitable to improve other properties. Examples of such auxiliary additives are acid scavengers, plasticizers, stabilizers (such as, for example, thermal stabilizers, oxidative stabilizers or antioxidants, light stabilizers, UV absorbers and chemical stabilizers), processing aids (such as, for example, mold release agents, nucleating agents, lubricants, blowing agents), pigments and colorants, and antistatic agents. An example of a suitable flame retardant synergist is zinc borate. By the term “zinc borate” is meant one or more compounds having the formula (ZnO)ₓ(B₂O₃)_{y}(H₂O)_{z}.

The composition according to the invention may comprise one or more other LDS additives, next to the LDS additive comprising the tin-based metal oxide (Component (B)). Such other LDS additives are selected and used in such amounts that the color requirements for the composition are still met. Typically, such other LDS additives will be used in relative small amounts, generally less than the amount of the LDS additive comprising the tin-based metal oxide, if at all. Preferably, the composition comprises the other LDS additive and the LDS additive comprising the tin-based metal oxide in a weight ratio in the range of 0:100-25:75, more particularly 0:100-10:90. Most preferably, to achieve compositions with the lightest colors, the composition does not comprise another LDS additive next to the LDS additive comprising the tin-based metal oxide. Examples of other LDS additives optionally comprised in the composition according to the invention include, but are not limited to, spinel based metal oxides and copper salts, or a mixture including at least one of the foregoing LDS additives. Examples of suitable copper salts are copper hydroxide phosphate, copper phosphate, copper sulfate, cuprous thiocyanate. Spinel based metal oxides are generally based on heavy metal mixtures, such as in copper chromium oxide spinel, e.g. with formula CuCr2O4, nickel ferrite, e.g. spinel with formula NiFe2O4, zinc ferrite, e.g. spinel with formula ZnFe2O4, and nickel zinc ferrite, e.g. spinel with formula ZnₓNi₍₁₋ₓ₎Fe₂O₄ with x being a number between 0 and 1.

The composition may suitably comprise further components enhancing the LDS properties, e.g. other components having a synergistic effect on the LDS properties, other than the metal salt (C). Suitably, the composition comprises TiO2. The advantage of the composition comprising both TiO2 and the metal salt of a phosphinic acid or a diphosphinic acid, or any mixtures thereof, is that the LDS properties are significantly enhanced to a level, for which still less TiO2 is needed than for corresponding compositions not containing the metal salt (C). Furthermore, in such compositions further comprising a reinforcing agent, the mechanical properties are better retained compared to corresponding reinforced compositions with the same level of LDS performance comprising more TiO2 but no LDS synergist (C).

In the composition present invention, the one or more further components (E) may be present in an amount varying over a wide range, suitably in a range of 0-30 wt. %, for example in a range of 0.01-25 wt. %. The total amount of other components (E) can be, for example, about 1-2 wt. %, about 5 wt. %, about 10 wt. %, or about 20 wt. %. Correspondingly, the sum of (A), (B), (C) and (D) suitably is at least 70 wt. %, preferably at least 75 wt. %. Herein the weight percentages (wt. %) are relative to the total weight of the composition. relative to the total weight of the composition. In other words, the sum of the amounts of (A), (B), (C), (D) and (E) is 100 wt. %.

In a particular embodiment, the composition comprises at least one other component, and the amount of (E) is in the range of 0.5-15 wt. %, more particular 1-10 wt. %. Correspondingly, (A), (B), (C) and (D) are present in a combined amount in the range of 85-99.99 wt. %, respectively 90-99 wt. %, relative to the total weight of the composition.

The compositions according to the invention can be prepared by standard processes suitable for producing thermoplastic compositions. Suitably, the thermoplastic polymer, the LDS additive and the metal (di)phosphinate and the optional reinforcing agent and optional additional ingredients are melt-blended. Part of the materials may be mixed in a melt-mixer, and the rest of the materials may then be added and further melt-mixed until uniform. Melt-blending may be carried out using any appropriate method known to those skilled in the art. Suitable methods may include using a single or twin-screw extruder, blender, kneader, Banbury mixer, molding machine, etc. Twin-screw extrusion is preferred, particularly when the process is used to prepare compositions that contain additives such as flame retardants, and reinforcing agent. The compositions of the present invention may be conveniently formed into a variety of articles using injection molding, rotomolding and other melt-processing techniques.

The invention also relates to a molded part made of a thermoplastic composition according to the invention or any particular or preferred embodiment thereof. Suitably, the molded part has been subjected to further LDS processing steps, and constitutes one of the following embodiments, wherein either:
the thermoplastic composition is capable of being plated after being activated using a laser; or
the molded article comprises an activated pattern on the molded article, obtained by laser treatment and capable of being plated to form a conductive path after being activated by the laser treatment; or
the molded article comprises a plated metal pattern thereon forming a conductive path obtained by metal plating after activating by the laser treatment.

The invention also relates to an article of manufacture comprising a molded article made of a thermoplastic composition according to the invention or any particular or preferred embodiment thereof and comprising a plated metal pattern forming a conductive path thereon. Suitably, the article is an article selected from the group consisting of antennas (e.g. RF, WIFI, blue tooth, near field), sensors, connectors and housings for electronic devices, for example housings and frames for notebooks, mobile phones and PC tablets.

The invention also relates to a process for producing a circuit carrier by a laser direct structuring process. Suitably, the process for producing a circuit carrier, comprising steps of providing a molded part containing a thermoplastic composition according to the invention or any specific embodiment thereof, or molding such a thermoplastic composition, thereby obtaining a molded part; irradiating areas of said part on which conductive tracks are to be formed with laser radiation, and subsequently metalizing the irradiated areas.

The invention is further illustrated with the following examples and comparative experiments.

### Raw Materials

PPA semi-crystalline semi-aromatic polyamide: PA-4T/66 copolymer, Tm=320° C., Mn around 10,000 g/mol, Mw around 20,000 g/mol
PBT Polyester
Glass fibers A GF: standard grade for polyamides, 10 micrometer diameter
Glass fibers B GF: standard grade for polyesters, 10 micrometer diameter
LDS additive Stanostat CP5C (5 wt. % Sb2O3) ex Keeling and Walker
LDS Synergist Exolit OP1230, aluminum diethyl phosphinate (from Clariant)

### Compositions

EX-I PPA+GF (30 wt. %)+LDS additive (5 wt. %)+TiO2 (5 wt. %)+LDS Synergist (5 wt. %)
EX-II PPA+GF (30 wt. %)+LDS additive (5 wt. %)+FR (5 wt. %)
EX-III PBT+GF (30 wt. %)+LDS additive (5 wt. %)+TiO2 (5 wt. %)+LDS Synergist (5 wt. %)
CE-A PPA+GF (30 wt. %)+LDS additive (5 wt. %)+TiO2 (5 wt. %)
CE-B PPA+GF (30 wt. %)+LDS additive (5 wt. %)
CE-C PBT+GF (30 wt. %)+LDS additive (5 wt. %)+TiO2 (5 wt. %)

### EXAMPLES

The compositions of Example I and II and Comparative Example A and B, shown in Table 1 and 2 were prepared by melt-blending with the constituting components on a Werner & Pfleiderer ZE-25 twin screw extruder using a 330° C. flat temperature profile. The constituents were fed via a hopper, glass fibers were added via a side feed. Throughput was 20 kg/h and screw speed was 200 rpm. The settings typically resulted in a measured melt temperature between about 320 and about 350° C. The polymer melt was degassed at the end of the extruder. The melt was extruded into strands, cooled and chopped into granules.

The compositions of Example III and Comparative Example C, shown in Table 1 and 2 were prepared in the same manner as above. The settings were adopted for standard glass fiber reinforced polyester compositions.

### Injection Molding of Test Bars

Dried granulate material was injection molded in a mold to form test bars with a thickness of 4 mm conforming ISO 527 type 1A for tensile testing, ISO 179/1 eU for unnotched Charpy testing, ISO 179/1 eA for notched Charpy testing and ISO 75 for HDT testing. For the compositions of Example I and II and Comparative Experiments A and B the temperature of the melt in the injection molding machine was 340° C. The temperature of the mold was 100° C.

For the compositions of Example III and Comparative Experiment C the temperature of the melt in the injection molding machine and the temperature of the mold were adjusted using standard conditions for adopted for standard glass fiber reinforced polyester compositions.

### Test Bars for Mechanical Testing

The test bars were used to measure the mechanical properties of the compositions. All tests were carried out on test bars dry as made. The compositions and main test results have been collected in Tables 1 and 2.

### LDS Performance

The LDS behavior was tested with a 20W laser, applying different power levels ranging from 50% to 90% of the maximum laser power (max 20 W) and different pulsing frequencies (60 kHz, 80 kHz and 100 kHz), with a laser spot size of 40 μm diameter. Plating was done with a standard Ethone Plating bath with Cu only with a plating time of 10 minutes. Plating thickness was measured with 300 micron diameter X-ray beam, averaged over 3 different measurements for each of the process conditions. The measurements were based on calibrated data for copper films with certified thickness values. Results are given in Table 1.

TABLE 1
Compositions and test results for compositions of Examples
I-III (with LDS additive and synergist) and Comparative
Experiments A-C (with LDS additive, without synergyst):
LDS plating performance/L-value of compounds

| | EX-I | EX-II | EX-III | CE-A | CE-B | CE-C |
|---|---|---|---|---|---|---|
| LDS | 5 | 4 | 5 | 3 | 2-3 | 3 |
| Performance | | | | | | |
| L-Value | Very | High- | Very | High- | High | High- |
| | high | very | high | very | | very |
| | | high | | high | | high |

Legend: 1 = poor, 5 = excellent

1. Thermoplastic composition comprising a thermoplastic polymer, a laser direct structuring (LDS) additive and a LDS synergist, wherein the composition comprises:
(A) a thermoplastic polymer;
(B) a LDS additive comprising a tin-based metal oxide; and
(C) a metal salt of a phosphinic acid or a diphosphinic acid, or any mixtures thereof, in an amount of 0.5-7 wt. %, relative to the weight of the total composition.

2. Thermoplastic composition according to claim 1, wherein the composition has a CIELab colour value L* of at least 70.

3. Thermoplastic composition according to claim 1, wherein the LDS additive comprising the tin-based metal oxide is present in an amount of at least 1 wt. % with respect to the weight of the total composition.

4. Thermoplastic composition according to claim 1, wherein the metal salt (C) is present in an amount of at least 1 wt. % with respect to the weight of the total composition.

5. Thermoplastic composition according to claim 1, wherein the LDS additive comprising the tin-based metal oxide comprises a mixed metal oxide comprising at least tin and a second metal selected from the group consisting of antimony, bismuth, aluminum and molybdenum

6. Thermoplastic composition according to claim 5, wherein the weight ratio of the second metal to tin is at least 0.01:1.

7. Thermoplastic composition according to claim 1, wherein the LDS additive comprising the tin-based metal oxide comprises antimony-doped tin oxide.

8. Thermoplastic composition according to claim 1, wherein the LDS additive comprising the tin-based metal oxide comprises at least 20 wt. % of tin, relative to the total weight of the LDS additive comprising the tin-based metal oxide.

9. Thermoplastic composition according to claim 1, wherein the thermoplastic polymer comprises a polymer selected from the group consisting of a polyamide, a polyester, a polycarbonate and any mixtures thereof.

10. Thermoplastic composition according to claim 1, wherein the metal salt (C) comprises a metal selected from the group consisting of aluminum, zinc, and a mixture thereof.

11. Thermoplastic composition according to claim 1, wherein the composition comprises a reinforcing agent, preferably comprising a fibrous reinforcing agent, more preferably glass fibers.

12. Thermoplastic composition according to claim 1, wherein the composition comprises
(A) 30-80 wt. % of the thermoplastic polymer;
(B) 1-15 wt. % of the LDS additive comprising the tin-based metal oxide;
(C) 1-5 wt. % of the metal salt of phosphinic acid or diphosphinic acid, or any mixtures thereof,
(D) 0-60 wt. % of a reinforcing agent;
wherein the sum of (A), (B), (C) and (D) is at most 100 wt. %, and wherein the weight percentages (wt. %) are relative to the weight of the total composition.

13. Thermoplastic composition according to claim 1, wherein the composition comprises one or more further components (E) in a total amount of 0-30 wt. %, relative to the total weight of the composition, and wherein the sum of (A), (B), (C), (D) and (E) is 100 wt. %.

14. Molded part made of a thermoplastic composition as defined in claim 1.

15. Article selected from the group consisting of antennas, sensors, connectors and housings for electronic devices, comprising the thermoplastic composition as defined in claim 1.

16. Process for producing a circuit carrier by laser direct structuring, comprising providing a molded part containing a thermoplastic composition as defined in claim 1, irradiating areas of said part on which conductive tracks are to be formed with laser radiation, and subsequently metalizing the irradiated areas.
